(19) United States
(12) Patent Application Publication
(10) Pub. No.: US 2021/0024550 A1
(43) Pub. Date: Jan. 28, 2021

(54) SiC PRECURSOR COMPOUND AND THIN FILM FORMING METHOD USING THE SAME

(71) Applicant: DUKSAN TECHOPIA CO., LTD., Cheonan-si, Chungcheongnam-do (KR)

(72) Inventors: Ja Yeon KIM, Seocheon-gun, Chungcheongnam-do (KR); Hyoung Nam KIM, Jinju-si, Gyeongsangnam-do (KR); Seung Bae PARK, Daegu (KR); Sangwoong YOON, Seoul (KR); Soojin LEE, Hapcheon-gun, Gyeongsangnam-do (KR)

(73) Assignee: DUKSAN TECHOPIA CO., LTD., Cheonan-si, Chungcheongnam-do (KR)

(21) Appl. No.: 16/968,097

(22) PCT Filed: Mar. 5, 2019
(86) PCT No.: PCT/KR2019/002540

§ 371 Date: Aug. 6, 2020

(30) Foreign Application Priority Data
Mar. 7, 2018 (KR) 10-2018-0026800

(51) Int. Cl. C07F 7/10; C23C 16/36; C23C 16/455

(52) U.S. Cl. CPC C07F 7/10; C23C 16/45553; C23C 16/45527; C23C 16/36

(57) ABSTRACT

Provided is a SiC precursor for performing SiOCN thin film deposition and a method of forming SiOCN thin film, the method of forming thin film containing a silicon according to the subject matter is performed on a low temperature process that does not require a catalyst, and film deposition rate and process efficiency are excellent according to the subject matter.

### STATEMENT REGARDING GOVERNMENT SUPPORT

This work was supported by the Korea Institute of Energy Technology Evaluation and Planning (KETEP) and the Ministry of Trade, Industry & Energy (MOTIE) of the Republic of Korea (No. 20172010106080).

### BACKGROUND

### Technical Field

The present invention relates to a SiC precursor for performing SiOCN thin film deposition used as a gate spacer in a semiconductor device, and a thin film forming method using the same.

### Background Art

In the manufacture of semiconductor devices, silicon oxide films and silicon nitride films are respectively manufactured in various thicknesses and by various methods. The silicon oxide film not only is stable, but also has excellent bonding properties with silicon semiconductor substrates and excellent electrical insulation properties. Thus, the silicon oxide film is often used as an insulator and also used for field oxide, pad oxide, interlayer insulator, capacitor insulator, etc.

In general, a silicon oxide film is one of the most commonly used thin films in semiconductors because it has excellent interface properties with silicon and excellent dielectric properties. In the manufacture of silicon-based semiconductor devices, silicon oxide films can be used for gate insulation layers, diffusion masks, sidewall spacers, hard masks, anti-reflection coating, passivation and encapsulation, and various other applications.

Conventionally, the following two methods are widely used as a usual method for depositing a silicon oxide film: (1) an oxidation process in which silicon is oxidized at a temperature above 1000° C.; and (2) a chemical vapor deposition (CVD) process in which two or more sources are provided at a temperature of 600° C. to 800° C. However, these methods induce diffusion at the interface due to the high deposition temperature, especially diffusion of dopants in the wafer, thereby degrading the electrical properties of the device.

As a method for solving these problems, a method of forming a silicon oxide film at a temperature of less than 200° C. using a catalyst and a small amount of a source is disclosed in U.S. Pat. No. 6,090,442. The method disclosed in U.S. Pat. No. 6,090,442 uses a catalyst capable of depositing silicon oxide even at temperatures of 200° C. or lower.

However, when the silicon oxide film is deposited at a room temperature to a temperature of 50° C., the temperature inside the reactor is low, so that reaction by-products and unreacted solutions such as HCDS and H₂O are not easily removed. These by-products are present as particles in the thin film after the deposition, which cause a problem that the properties of the thin film are deteriorated. In contrast, when a silicon oxide film is deposited at a temperature of 50° C. or higher, by-products such as reacted and unreacted HCDS and H₂O can be easily removed, but the deposition rate of the thin film is very low, resulting in a decrease in the yield of the device.

In addition, as a method for using a plasma process at a low temperature, a method of depositing a silicon oxide film at low temperature using plasma enhanced chemical vapor deposition (PECVD) has been used, but there was a drawback in that the silicon dioxide film deposited from silane through the PECVD at a temperature of about 200° C. or lower has poor quality.

Meanwhile, as the semiconductor device is highly integrated, the gate channel length is reduced. The reduction of the channel length can lead to a deterioration in the gate characteristics. Recently, in order to solve the problems of the gate characteristic due to the reduction in the channel length, a process of lowering a temperature in semiconductors is frequently pursued. Lowering the temperature is derived from the reduction in the size of semiconductors and the introduction of ion implantation processes, and is intended to prevent diffusion of the ion implantation layer by a low temperature process. In particular, it is intended to keep the channel length constant by preventing diffusion of the ion implantation layer in a source/drain region through the low-temperature process. In general, SiN or SiO₂ is often used as gate spacers, and most of these processes are performed at a high temperature of 700° C. or more using a CVD method, so that diffusion of the ion implantation layer in the source/drain region occurs, and the channel length is reduced, which results in deterioration of gate characteristics. However, when the CVD SiN and SiO₂ are replaced by an ALD process as the gate spacer, the gate characteristics can be improved.

### PRIOR ART LITERATURE

1. Korean Patent Publication No. 10-2013-0116210 published on Oct. 23, 2013
2. Korean Patent Publication No. 10-2015-0111874 published on Oct. 6, 2015

### Object, Technical Solution and Effects of the Invention

The present invention has been designed to solve the above-mentioned problems of the prior arts, and therefore, an object thereof is to provide to a SiC precursor for performing an atomic layer deposition (ALD), and a method for forming a silicon-containing thin film using the same.

In another aspect of the present invention, the present invention provides a SiC precursor represented by Formula 1.

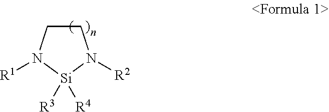

The method for forming a silicon-containing thin film according to the present invention is performed through a process requiring no separate catalyst, and has excellent film deposition rate and process efficiency.

In addition, the silicon-containing thin film formed according to the present invention has excellent electrical properties such as a dielectric constant, and thus can be effectively used for forming structures of various devices including semiconductor devices.

### BRIEF DESCRIPTION OF THE DRAWINGS

FIG. 1 is a graph showing ¹H NMR analysis data of a final product prepared according to one embodiment of the present invention.

FIG. 2 is a graph showing ¹³C NMR analysis data of a final product prepared according to one embodiment of the present invention.

FIG. 3 is a graph showing ²⁹Si NMR analysis data of a final product prepared according to one embodiment of the present invention.

FIG. 4 is a graph showing the results of thermogravimetric analysis (TGA) of a final product prepared according to one embodiment of the present invention.

FIG. 5 is a schematic view showing a process for a method of depositing a SiOCN thin film according to one embodiment of the present invention.

FIG. 6 is a simplified view showing a gas injection sequence applied to atomic layer deposition in a method of depositing a SiOCN thin film according to one embodiment of the present invention.

FIG. 7 is a graph showing numerical values in which the thickness of the thin film deposited in the method of depositing the SiOCN thin film according to one embodiment of the present invention is converted in terms of GPC according to the process temperature.

FIGS. 8 to 10 are graphs showing the results of XPS analysis at 500° C., 550° C., and 600° C., respectively, for the thin films deposited by the method of depositing the SiOCN thin films according to one embodiment of the present invention.

### DETAILED DESCRIPTION

In one embodiment of present invention, the present invention provides a SiC precursor represented by Formula 1.

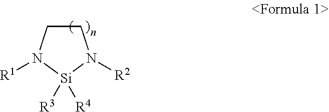

In Formula 1, R¹ and R² may be each independently a C₁-C₆ alkyl group, preferably, methyl, ethyl, n-propyl, iso-propyl, n-butyl, or iso-butyl, more preferably, n-propyl, iso-propyl, n-butyl, or iso-butyl, most preferably, all may be iso-propyl.

R³ and R⁴ may be each independently hydrogen or a C₁-C₄ alkyl group, preferably, H(hydrogen), methyl, ethyl, n-propyl, iso-propyl, n-butyl, or iso-butylH, more preferably, H(hydrogen), methyl or ethyl, most preferably, one of R³ and R⁴ may be hydrogen and the other may be methyl.

n is an integer 0-3, preferably, 1.

Where n is 0, 1, 2, or 3, Formula 1 is as follows, respectively.

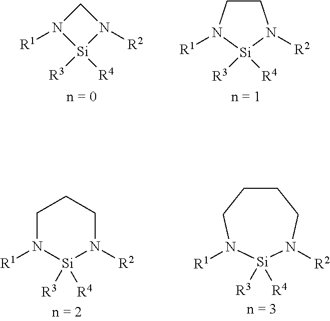

The SiC precursor defined by Formula 1 may be prepared by Reaction Scheme 1 below, the SiC precursor according to Reaction Scheme 1 can be synthesized using a non-polar solvent such as hexane, pentane, heptane, benzene or toluene as a reaction solvent, or using a polar solvent such as diethyl ether, petroleum ether, tetrahydrofuran or 1,2-dimethoxyethane as a reaction solvent.

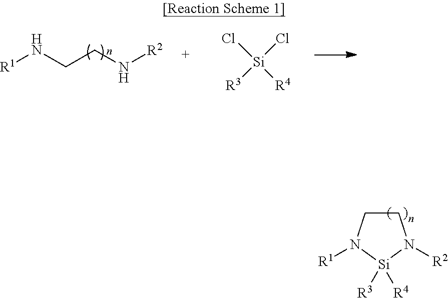

More specifically, the SiC precursor defined by Formula 1 may be prepared by Reaction Scheme 2 below.

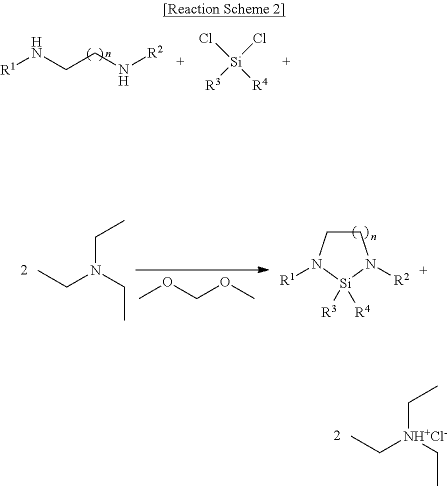

In Formulas 1 and 2, n and R¹ to R⁴ are the same as defined above.

Scheme Reaction 1 and 2 are each performed in a non-polar solvent selected from the group consisting of hexane, pentane, heptane, benzene and toluene, or in a polar solvent selected from the group consisting of diethyl ether, petroleum ether, tetrahydrofuran and 1,2-dimethoxyethane.

In another embodiment, the present invention provides a method of depositing a SiOCN thin film on a silicon substrate using the SiC precursor of Formula 1.

In one embodiment, the present invention provides a method forming a SiOCN thin film comprising a deposition step vaporizing one or more of the SiC precursor represented by Formula 1 on a silicon substrate, or a metal, ceramic or plastic structure.

In another embodiment, the present invention provides a method of forming a SiOCN thin film using chemical vapor deposition (CVD) or atomic layer deposition (ALD) in the deposition step.

In another embodiment of the present invention, the deposition step may be performed at 400-550° C.

In another embodiment, the present invention provides a method forming a SiOCN thin film by an atomic layer deposition method, wherein a method forming a SiOCN thin film comprises positioning the substrate in a reaction chamber; injecting a gaseous SiC precursor into the reaction space; removing excess SiC precursor using an inert gas; contacting the oxygen precursor with SiC species adsorbed on the substrate; removing excess oxygen precursor and reaction byproducts using an inert gas; contacting the nitrogen precursor with SiC—O species adsorbed on the substrate; and removing excess nitrogen precursor and reaction byproducts using an inert gas. The above steps can be repeated to achieve a desired thickness of the SiOCN thin film.

Hereinafter, embodiments of the present invention will be described in more detail with reference to examples. These examples are for specifically explaining the present invention, and the scope of the present invention is not limited by the examples.

Preparation Example of SiC Precursor

The SiC precursor according to the present invention was prepared according to the following procedure. The related reaction is shown in Reaction Scheme 3.

20 g of Diisopropylethylenediamine, 27 g of triethylamine, and 500 g of methylal were added to a reactor under dry N₂, and the mixture was stirred. The temperature of the reactor was cooled to −20° C. under a nitrogen atmosphere, and then 16 g of dichloromethylsilane was slowly added dropwise thereto while stirring. After the addition was completed, the reactor temperature was slowly raised to room temperature. The mixed reaction solution was stirred for one day at room temperature, a white solid was removed, thereby obtaining a filtrate. The filtrate was subjected to simple distillation to remove the solvent. After removal of the solvent, the product was purified under reduced pressure to give 13 g of a desired compound (yield: 50%) (5 torr, 56° C.).

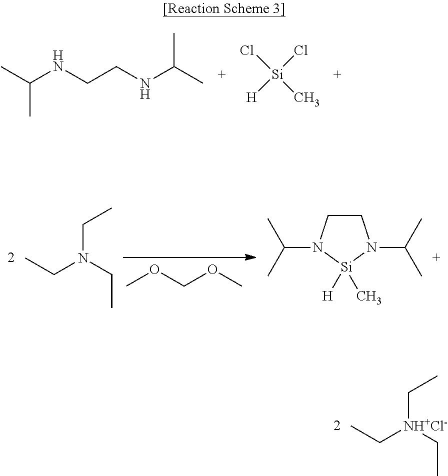

Analysis of Final Product

The structure of the final product obtained according to Example of the present invention was analyzed using ¹H nuclear magnetic resonance method (¹H NMR), ¹³C nuclear magnetic resonance method (¹³C NMR), ²⁹Si NMR, and thermogravimetric analysis (TGA).

(¹H NMR Analysis Data)

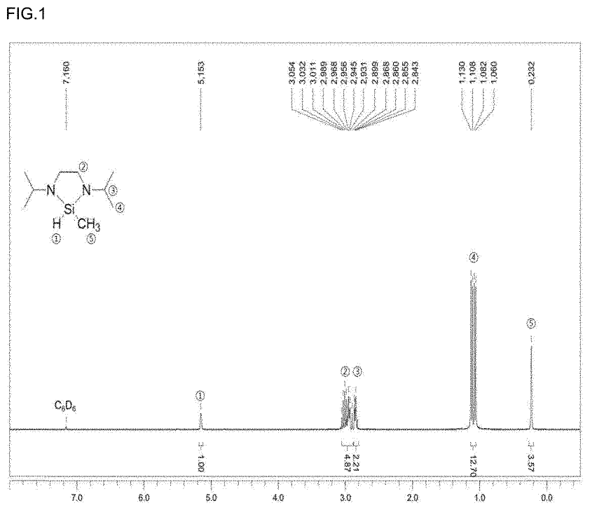

FIG. 1 shows ¹H NMR analysis data of a final product prepared according to one embodiment of the present invention.

(¹³C NMR Analysis Data)

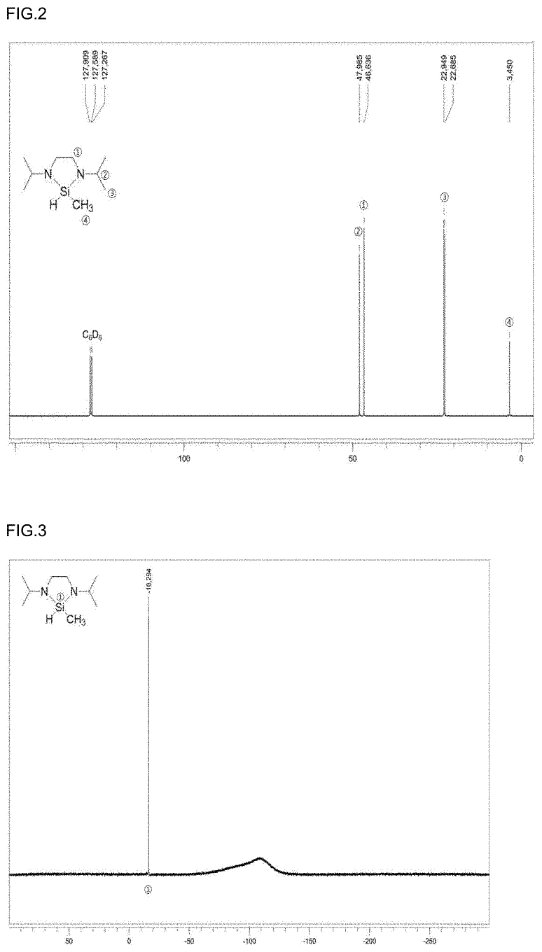

FIG. 2 shows ¹C NMR analysis data of a final product prepared according to one embodiment of the present invention.

(²⁹Si NMR Analysis Data)

FIG. 3 shows ¹Si NMR analysis data of a final product prepared according to one embodiment of the present invention.

(Thermal Analysis Data)

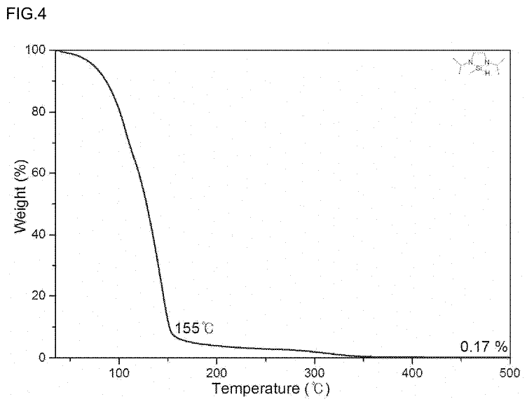

FIG. 4 shows the results of thermogravimetric analysis (TGA) of a final product prepared according to one embodiment of the present invention.

SiOCN Thin Film Deposition: SiOCN ALD Thin Film Deposition

SiOCN thin films were deposited using the SiC precursor according to the present disclosure.

The method of depositing a SiOCN thin film used as a gate spacer in a semiconductor device comprises the steps of: positioning a substrate into a reaction chamber; injecting a gaseous SiC precursor into a reaction space; removing excess SiC precursor using an inert gas; contacting an oxygen precursor with SiC species adsorbed on the substrate; removing excess oxygen precursor and reaction by-products using an inert gas; contacting a nitrogen precursor with the SiC—O species adsorbed on the substrate; and removing excess nitrogen precursor and reaction by-products using an inert gas.

The above steps are repeated so as to achieve a silicon nitride film having a desired thickness.

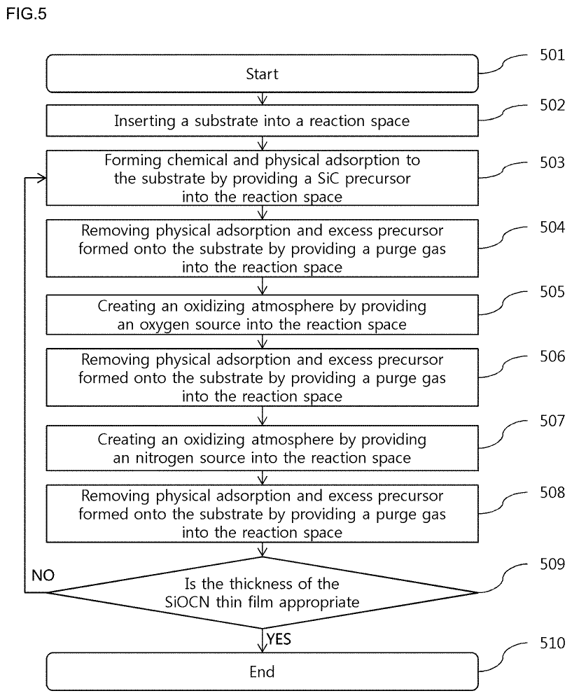

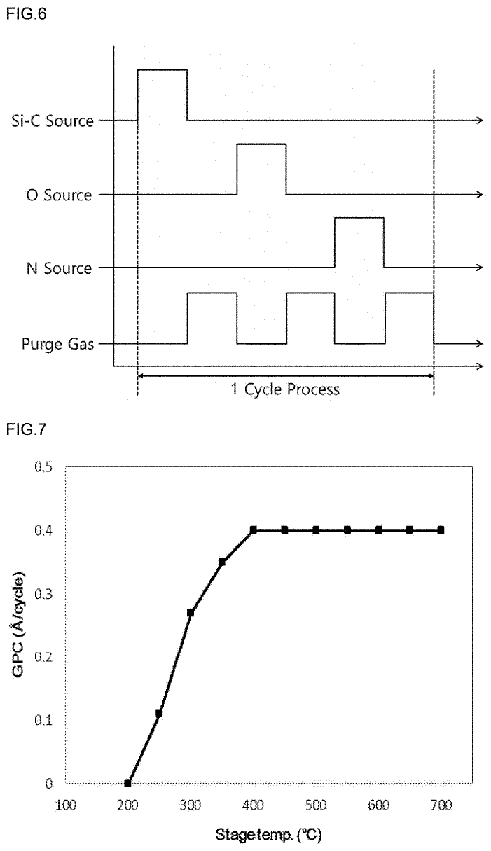

The above process is shown in FIG. 5, and the gas injection sequence applied to the atomic layer deposition is shown in FIG. 6.

As shown in FIG. 5, a method of depositing a SiOCN thin film used as a gate spacer in a semiconductor device according to the present disclosure starts from a starting step 501. First, a substrate for depositing a SiOCN thin film is inserted into a reaction space (step 502), and a SiC precursor is fed into a reaction space to form chemical and physical adsorption to the substrate (step 503). Subsequently, a purge gas is fed into a reaction space to remove physical adsorption and excess precursor formed onto the substrate (step 504), and an oxygen source is fed into the reaction space to create an oxidizing atmosphere (step 505). Then, a purge gas is fed into the reaction space to remove physical adsorption and excess precursor formed onto the substrate (step 506). Then, a nitrogen source is fed into the reaction space to create an oxidizing atmosphere (step 507), and the purge gas is fed into the reaction space to remove physical adsorption and excess precursor formed onto the substrate (step 508). The thickness of the SiOCN thin film formed according to the above process is measured to confirm whether the thickness is appropriate (step 509).

If the thickness is not appropriate, a series of processes from a step of feeding a SiC precursor into the reaction space to form chemical and physical adsorption onto the substrate (step 503) to a step of feeding a purge gas into the reaction space to remove the physical adsorption and excess precursor formed onto the substrate (step 508) are repeated. The thickness of the formed SiOCN thin film is measured to confirm whether it is appropriate (step 509). If the thickness of the SiOCN thin film is appropriate, the process ends (step 510).

Evaluation of Optimum Process Conditions for Atomic Layer Deposition

To find out the optimum process conditions for atomic layer deposition of the SiC precursor obtained according to the present disclosure, the following evaluation process was performed.

### Evaluation Example 1

In order to confirm the application range of atomic layer deposition of the synthesized SiC precursor, evaluation was performed at a process temperature of 200° C., 250° C., 300° C., 350° C., 400° C., 450° C., 500° C., 550° C., 600° C., 650° C. and 700° C. to confirm the thickness of the SiOCN thin film formed using an ellipsometer. The measured thickness is converted into GPC, which is a deposition thickness per cycle, and is schematized in FIG. 7.

As a result of evaluating the synthesized SiC precursor, the application range of atomic layer deposition was considered to be applicable at a process temperature of 400° C. to 700° C., and the obtained GPC value was about 0.4 Å/cycle.

### Evaluation Example 2

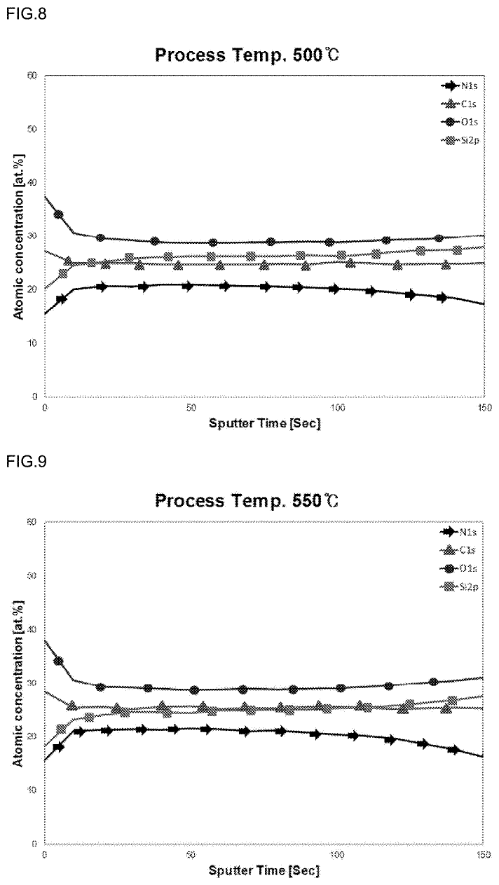

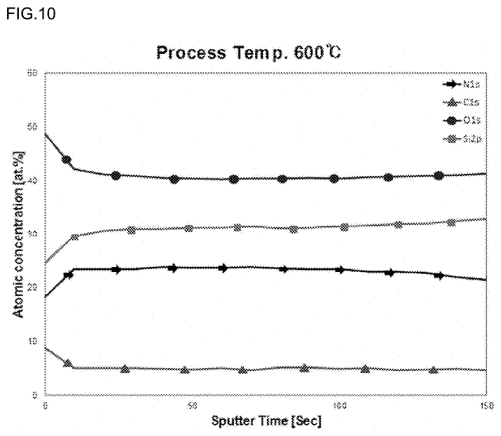

The results of XPS analysis at 500° C., 550° C., and 600° C., respectively, with respect to the process temperatures confirmed in Evaluation Example 1 are shown in FIGS. 8 to 10.

As a result of XPS analysis of the deposited thin film, the carbon content of the formed thin film was measured to be 5 atom % or less at a temperature of 600° C. or higher. It was analyzed that in the synthesized SiC precursor, desorption of carbon occurs at a process temperature of 600° C. or higher. It is considered that the process temperature applicable to the SiOCN thin film deposition process of the synthesized SiC precursor is 400° C. to 550° C.

1. A SiC precursor compound of Formula 1: 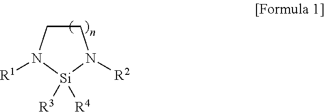
wherein R¹ and R² are each independently a C₁-C₆ alkyl group, R³ and R⁴ are each independently hydrogen or a C₁-C₄ alkyl group, and n is an integer 0-3.

2. The SiC precursor compound of claim 1, wherein R¹ and R² are each independently n-propyl, iso-propyl, n-butyl, or iso-butyl, and R³ and R⁴ are each independently hydrogen, methyl or ethyl.

3. The SiC precursor compound of claim 2, wherein R¹ and R² are iso-propyl, one of R³ and R⁴ may be hydrogen and the other may be methyl, and n is an integer of 1.

4. A method of manufacturing SiC precursor compound represented by Formula 1 according to Reaction Scheme 1: 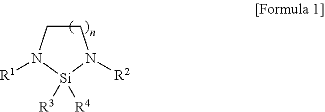 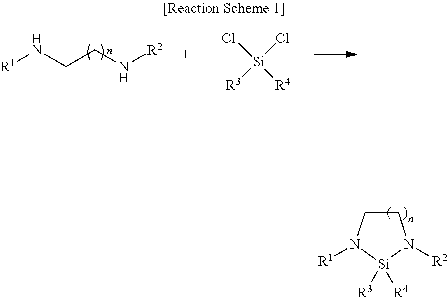
wherein:
R¹ and R² are each independently a C₁-C₆ alkyl group, R³ and R⁴ are each independently hydrogen or a C₁-C₄ alkyl group, n is an integer 0-3, and
the Reaction Scheme 1 is performed in a non-polar selected selected from the group consisting of hexane, pentane, heptane, benzene and toluene, or in a polar solvent selected from the group consisting of diethyl ether, petroleum ether, tetrahydrofuran and 1,2-dimethoxyethane.

5. A method of forming a SiOCN thin film comprising a deposition step vaporizing one or more of the SiC precursor according to claim 1 on a silicon substrate, or a metal, ceramic or plastic structure.

6. The method of forming a SiOCN thin film of claim 5, wherein chemical vapor deposition (CVD) or atomic layer deposition (ALD) is used in the deposition step.

7. The method of forming a SiOCN thin film of claim 6, wherein the deposition step is performed at 400-550° C.

8. The method of forming a SiOCN thin film of claim 7, wherein the atomic layer deposition is used and the method comprises a) positioning the substrate in a reaction chamber; b) injecting a gaseous SiC precursor into the reaction space; c) removing excess SiC precursor using an inert gas; d) contacting the oxygen precursor with SiC species adsorbed on the substrate; e) removing excess oxygen precursor and reaction byproducts using an inert gas; f) contacting the nitrogen precursor with SiC—O species adsorbed on the substrate; and g) removing excess nitrogen precursor and reaction byproducts using an inert gas.

9. A method of forming a SiOCN thin film comprising a deposition step vaporizing one or more of the SiC precursor according to claim 2 on a silicon substrate, or a metal, ceramic or plastic structure.

10. The method of forming a SiOCN thin film of claim 9, wherein chemical vapor deposition (CVD) or atomic layer deposition (ALD) is used in the deposition step.

11. The method of forming a SiOCN thin film of claim 10, wherein the deposition step is performed at 400-550° C.

12. The method of forming a SiOCN thin film of claim 11, wherein the atomic layer deposition is used and the method comprises a) positioning the substrate in a reaction chamber; b) injecting a gaseous SiC precursor into the reaction space; c) removing excess SiC precursor using an inert gas; d) contacting the oxygen precursor with SiC species adsorbed on the substrate; e) removing excess oxygen precursor and reaction byproducts using an inert gas; f) contacting the nitrogen precursor with SiC—O species adsorbed on the substrate; and g) removing excess nitrogen precursor and reaction byproducts using an inert gas.

13. A method of forming a SiOCN thin film comprising a deposition step vaporizing one or more of the SiC precursor according to claim 3 on a silicon substrate, or a metal, ceramic or plastic structure.

14. The method of forming a SiOCN thin film of claim 13, wherein chemical vapor deposition (CVD) or atomic layer deposition (ALD) is used in the deposition step.

15. The method of forming a SiOCN thin film of claim 14, wherein the deposition step is performed at 400-550° C.

16. The method of forming a SiOCN thin film of claim 15, wherein the atomic layer deposition is used and the method comprises a) positioning the substrate in a reaction chamber; b) injecting a gaseous SiC precursor into the reaction space; c) removing excess SiC precursor using an inert gas; d) contacting the oxygen precursor with SiC species adsorbed on the substrate; e) removing excess oxygen precursor and reaction byproducts using an inert gas; f) contacting the nitrogen precursor with SiC—O species adsorbed on the substrate; and g) removing excess nitrogen precursor and reaction byproducts using an inert gas.
